(19) United States
(12) Patent Application Publication
(10) Pub. No.: US 2002/0055257 A1
(43) Pub. Date: May 9, 2002

(54) METHOD FOR FABRICATING SEMICONDUCTOR DEVICE

(76) Inventor: GYOUNG SEON GIL, CHOLLABUK-DO (KR)

Correspondence Address: BIRCH STEWART KOLASCH & BIRCH LLP, P O BOX 747, FALLS CHURCH, VA, 22040

(21) Appl. No.: 09/457,664

(22) Filed: Dec. 9, 1999

(30) Foreign Application Priority Data
Mar. 18, 1999 (KR) 9233/1999

(51) Int. Cl. H01L 21/302; H01L 21/461

(52) U.S. Cl. 438/689

(57) ABSTRACT

Method for fabricating a semiconductor device for forming field oxide films on an isolation region of a plurality of active regions each having a long axis and a short axis, including the steps of forming first field oxidation mask layers on all active regions, forming a second field oxidation mask layer on an isolation region which isolates one active region and an adjacent active region in a long axis direction thereof, the second field oxidation mask layer connecting the first field oxidation mask layers, and conducting a field oxidation such that field oxide films grow at exposed portions and portion in contact with bottom sides of the second field oxidation mask layer to encroach into the bottom sides of the second field oxidation mask layer, to form a field oxide film on the exposed portions and on an entire portion of the bottom side of the second field oxidation mask layer.

### BACKGROUND OF THE INVENTION

1. Field of the Invention

The present invention relates to a semiconductor device, and more particularly, to a method for fabricating a semiconductor device, which allows to secure an active region in a field oxidation process, effectively.

2. Background of the Related Art

In general, a device isolation layer may be formed by conducting a field oxidation using an anti-oxidation insulating layer as a mask, or by an STI in which a trench is formed in a semiconductor substrate and the trench is stuffed with an insulating material. Currently, under a mass production system, the device isolation layer is mostly formed by the field oxidation under a mass production system.

A related art method for forming a field oxide film in a semiconductor device will be explained with reference to the attached drawings. FIG. 1 illustrates a layout after patterning of a mask layer for conducting the related art field oxidation, and FIGS. 2a˜2d illustrates sections across line A-A′ in FIG. 1 showing the steps of a related art field oxidation process. A layout of mask layers formed for defining active regions and field regions in a related art field oxidation process is as shown in FIG. 1. Mask layers of island forms of, for example, anti-oxidation material, are patterned on an active region. After defining the active region thus, the field oxidation process is conducted to form a field oxide film on a device isolation region. Detail of the field oxidation process is as follows.

Referring to FIG. 2a, a buffer oxide film 22 is formed on a semiconductor substrate 21. Then, a nitride layer 23 is formed on the buffer oxide film 22 formed on the semiconductor substrate 21 and a photoresist layer 24 is formed on the nitride layer 23. As shown in FIG. 2b, a field oxidation mask is used in subjecting the photoresist layer 24 to selective exposure and development. The patterned photoresist layer 24a is used as mask in removing the exposed nitride layer 23 selectively, to leave the patterned nitride layer 23a only on portions excluding the device isolation region. Then, as shown in FIG. 2c, the photoresist layer 25a used as a mask in removing the nitride layer 23a is removed. And, the nitride layer 23a patterned to leave only on the active region is used as a mask in conducting a field oxidation to form a field oxide film 25 on the device isolation region. As shown in FIG. 2d, the nitride layer 23a used as a mask in the field oxidation process is removed, and the buffer oxide film 22 is removed to expose the semiconductor substrate 21 in the active region.

The related art process for forming a field oxide film is involved in the following reduction of the active region. FIG. 3 illustrates a layout showing a size change of an active region following the related art process for forming a field oxide film. In the related art process for forming a field oxide film for a semiconductor device using a nitride layer as a mask, bird's beaks phenomena occurred, in which the field oxide film layer encroaches into the active region at edges of the nitride layer in the field oxidation process. ‘A’ region is an initially defined active region, and ‘B’ region shows a reduced state of the active region caused by excessive growth of the bird's beaks in the case when the field oxidation is conducted using the patterned mask layer. The reduction of active region is greater along a long axis than a short axis, that is, the reduction of the active region in ‘C’ region is the greater. ‘D’ region in FIG. 3 denotes a device isolation region in which a field oxide film is formed.

Thus, the related art process for forming a device isolation layer in a semiconductor device is involved in that an active region fails to secure an initially patterned area due to occurrence of excessive oxidation, like bird's beak, in which a field oxide film encroaches into the active region at edges of nitride layer used as a mask in the field oxidation process, that makes a fabrication process difficult in view of device high density packing and micronization and unfavorable in view of yield, and particularly, makes security of contact allowance required for formation of a cell storage node in a process for fabrication of device, such as DRAM difficult. If cleaning is done excessively for securing the contact allowance, a hump is caused in the vicinity of a width direction of a transistor (‘A’ portion in FIG. 3), which causes a threshold voltage reduction, an off current increase of a cell transistor, that deteriorates transistor performance.

### SUMMARY OF THE INVENTION

Accordingly, the present invention is directed to a method for fabricating a semiconductor device that substantially obviates one or more of the problems due to limitations and disadvantages of the related art.

An object of the present invention is to provide a method for fabricating a semiconductor device, which allows an effective security of an active region in a field oxidation process.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the method for fabricating a semiconductor device for forming field oxide films on an isolation region of a plurality of active regions each having a long axis and a short axis, includes the steps of forming first field oxidation mask layers on all active regions, forming a second field oxidation mask layer on an isolation region which isolates one active region and an adjacent active region in a long axis direction thereof, the second field oxidation mask layer connecting the first field oxidation mask layers, and conducting a field oxidation such that field oxide films grow at exposed portions and portion in contact with bottom sides of the second field oxidation mask layer to encroach into the bottom sides of the second field oxidation mask layer, to form a field oxide film on the exposed portions and on an entire portion of the bottom side of the second field oxidation mask layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention:

In the drawings:

FIG. 1 illustrates a layout after a mask layer is patterned for conducting a related art field oxidation;

FIGS. 2a˜2d illustrate sections across line A-A′ in FIG. 1 showing the steps of a related art field oxidation process;

FIG. 3 illustrates a layout showing a size change of an active region following the related art process for forming a field oxide film;

FIG. 4 illustrates a layout after a mask layer is patterned for conducting a field oxidation in accordance with a preferred embodiment of the present invention;

FIGS. 5a˜5d illustrate sections across line B-B′ in FIG. 4 showing the steps of a field oxidation process;

FIGS. 6a˜6d illustrate sections across line C-C′ in FIG. 4 showing the steps of a field oxidation process; and,

FIGS. 7a˜7d illustrate sections across line D-D′ in FIG. 4 showing the steps of a field oxidation process.

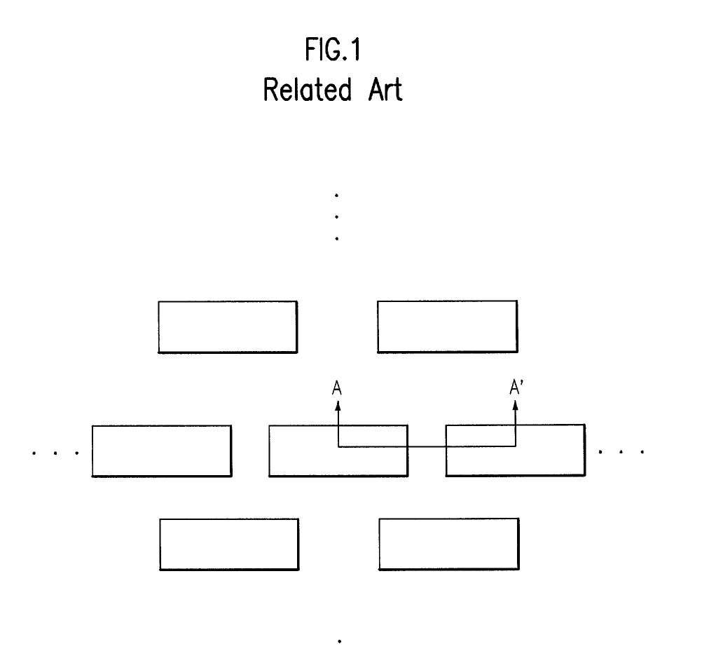

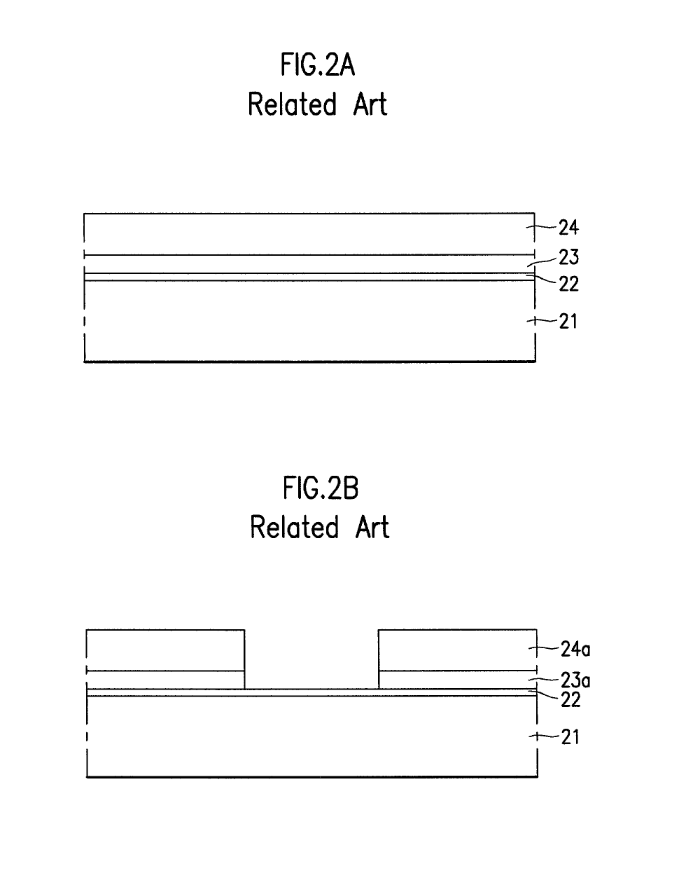

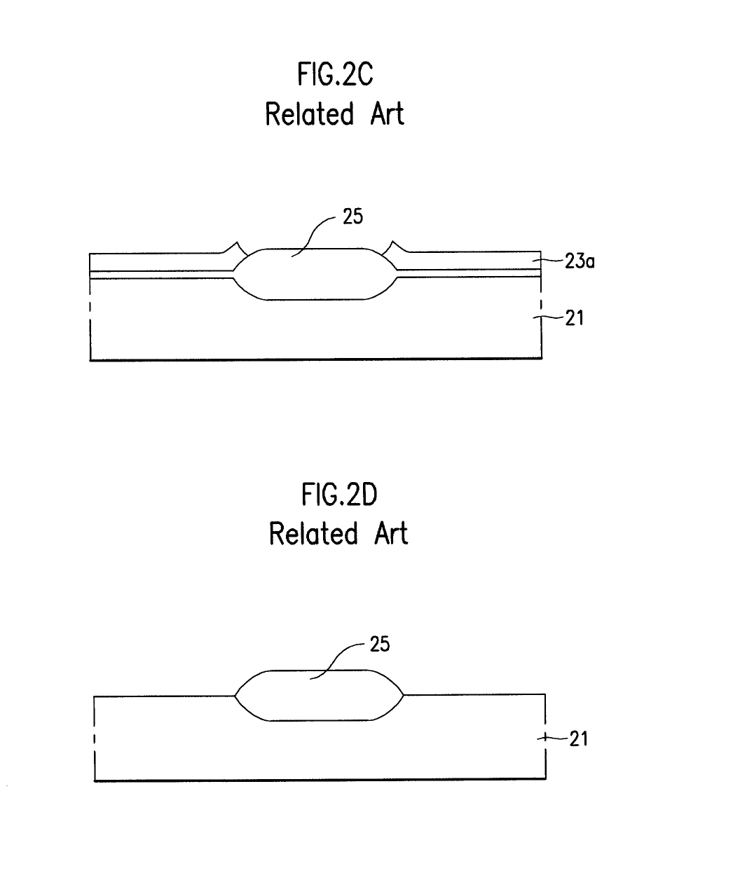

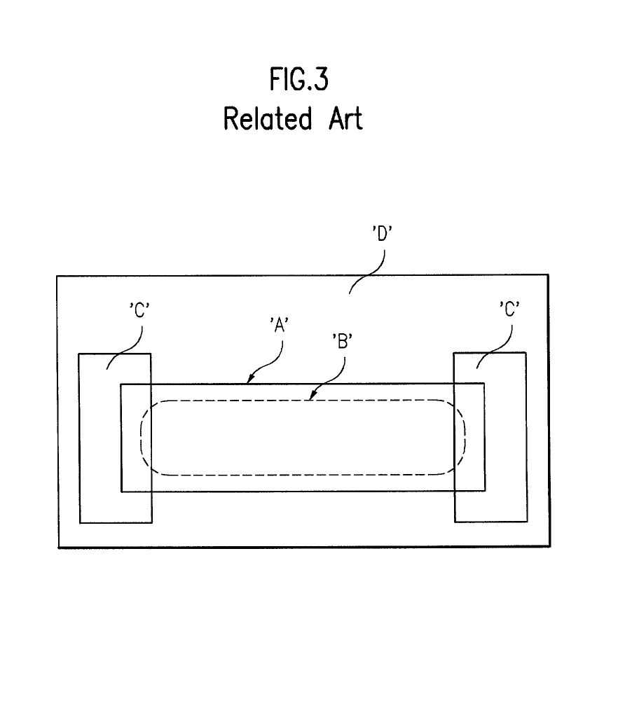

### DETAILED DESCRIPTION OF THE PREFERRED EMBODIMENT

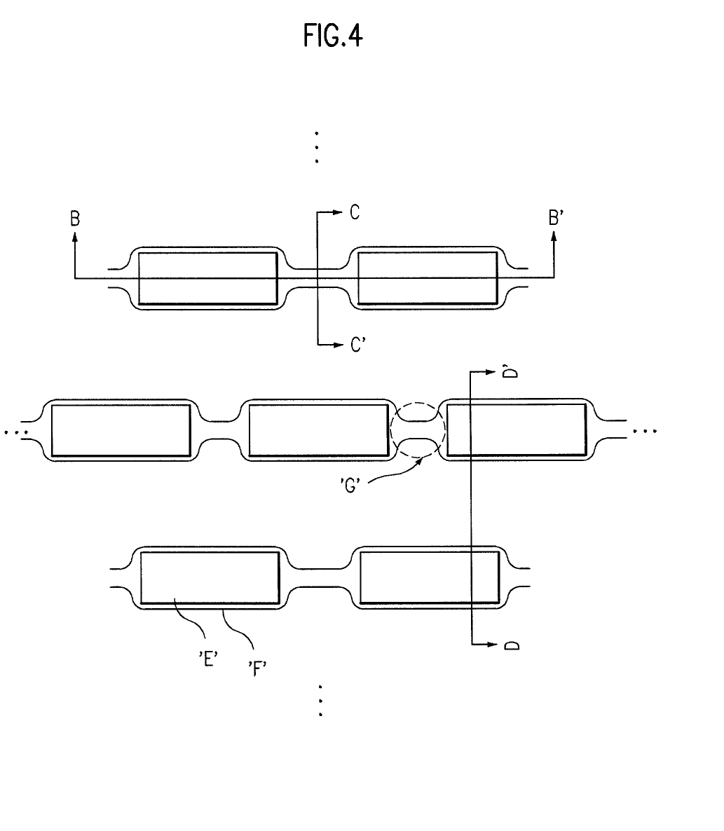

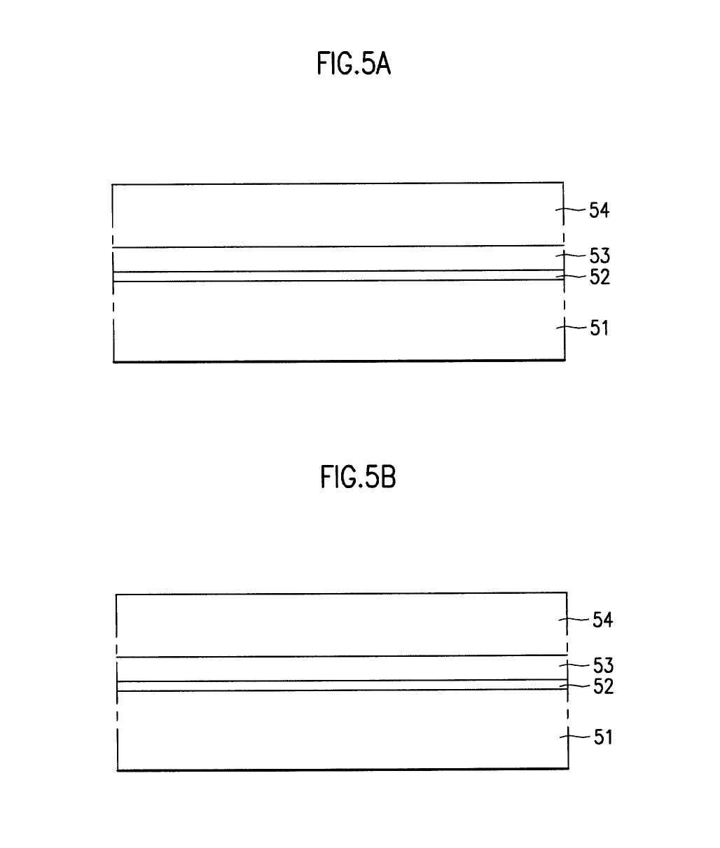

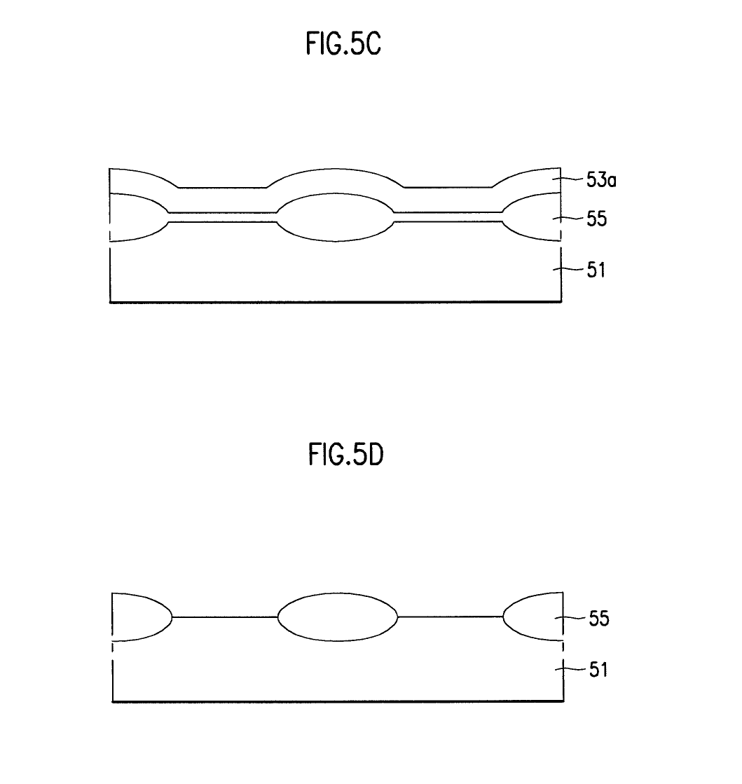

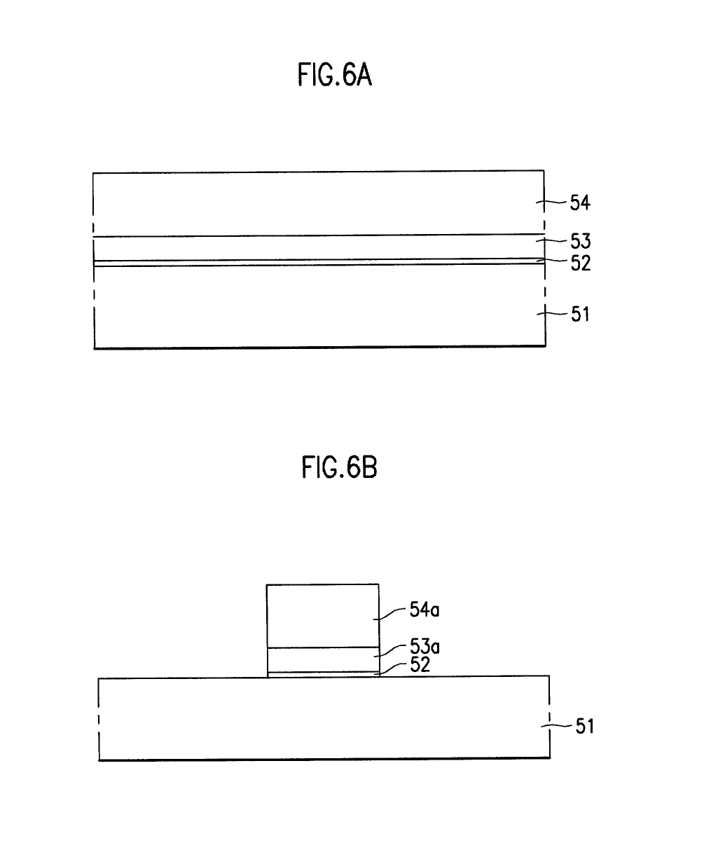

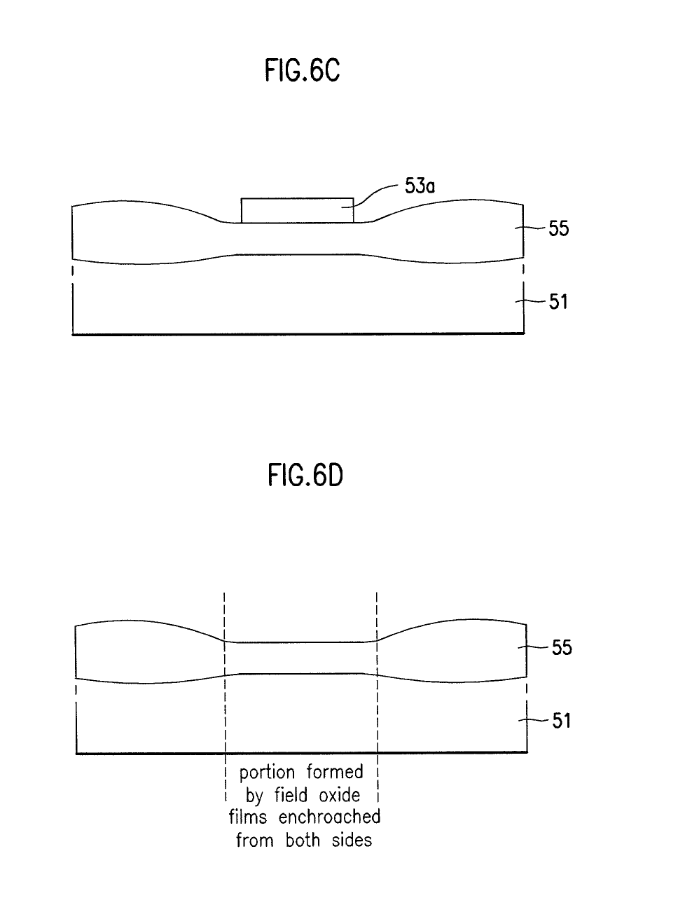

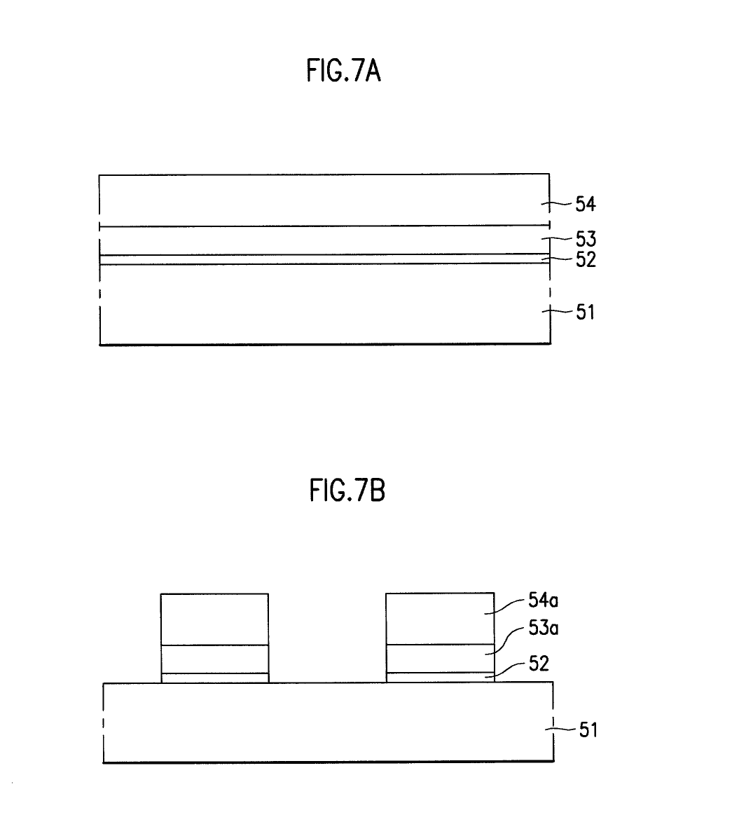

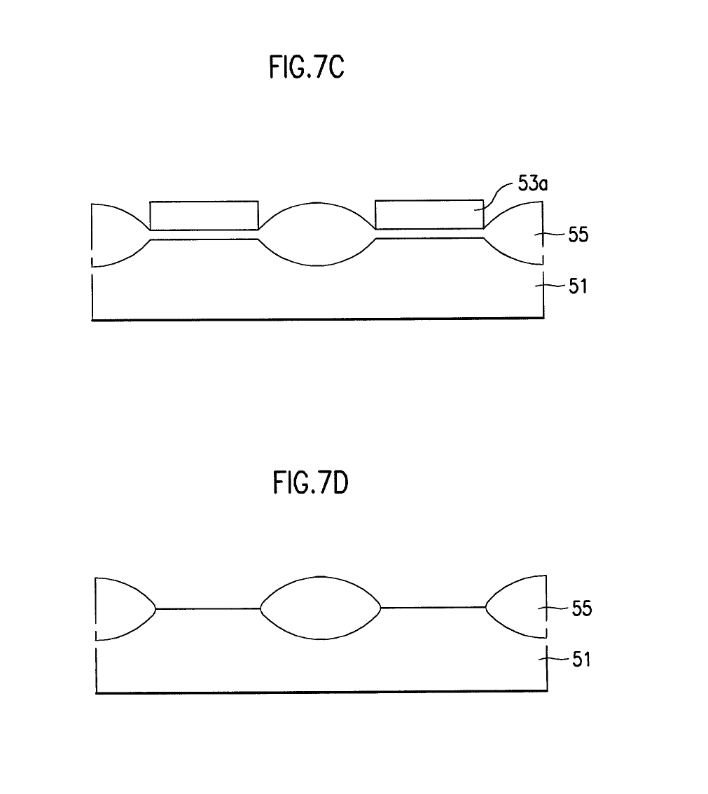

Reference will now be made in detail to the preferred embodiments of the present invention, examples of which are illustrated in the accompanying drawings. FIG. 4 illustrates a layout after a mask layer is patterned for conducting a field oxidation in accordance with a preferred embodiment of the present invention, FIGS. 5a˜5d illustrate sections across line B-B′ in FIG. 4 showing the steps of a field oxidation process, FIGS. 6a˜6d illustrate sections across line C-C′ in FIG. 4 showing the steps of a field oxidation process, and FIGS. 7a˜7d illustrate sections across line D-D′ in FIG. 4 showing the steps of a field oxidation process.

In the method for fabricating a semiconductor device of the present invention, in order to secure an adequate active region, a dummy field mask is formed on a field region which isolates one active region from an adjacent active region in a long axis direction thereof in field mask patterning before conducting a field oxidation process, for forming a field oxide film on an isolation region that isolates the one active region and the adjacent active region in a long axis direction thereof, of oxide grown from both sides of the dummy field mask in the field oxidation process. This field oxide film on the isolation region is formed for preventing a size reduction of an effective active region in a case when the field oxidation is conducted with the isolation region for isolating an active region from an adjacent active region in a long axis direction thereof is exposed from starting. That is, in a case when the field oxidation process is conducted with the device isolation region (‘G’ portion in FIG. 4) exposed from the starting of the field mask formation process, even if the device isolation region is provided for isolating an active regions, the field oxide film encroaches into the active region excessively, resulting in failure in securing an adequate active region required for fabrication of a device. Therefore, in the present invention, an active mask is formed on the ‘G’ region in FIG. 4 too (with a width which fully comes off by the field oxide film encroaching from both sides in the field oxidation process) before the field oxidation process is conducted. The ‘E’ region in FIG. 4 denotes an actually required effective active region, and ‘F’ region in FIG. 4 is a region the field oxidation mask layer with a process allowance is to be formed.

Referring to FIGS. 5a, 6a, and 7a, the method for fabricating a semiconductor device in accordance with a preferred embodiment of the present invention starts with forming a buffer oxide film 52, and a field oxidation mask material layer 53 on an entire surface of a semiconductor substrate 51 in succession. The field oxidation mask material layer 53 is formed of anti-oxidation material, mostly nitride. A photoresist layer 54 is formed on an entire surface of the field oxidation mask material layer 53. Then, as shown in FIGS. 5b, 6b and 7b, the photoresist layer 54 is subjected to patterning to leave the photoresist layer 54 only on an active region inclusive of the isolation region which isolates an active region and an adjacent active region in a long axis direction thereof. Then, the patterned photoresist layer 54a is used as a mask in removing the exposed field oxidation mask material layer 53, the buffer oxide film 52 selectively, for exposing a surface of the semiconductor substrate 51. In this instance, a surface of the semiconductor substrate 51 in the isolation region which isolates the active region and an adjacent active region in a short axis direction thereof is exposed fully. As shown in FIGS. 5c, 6c and 7c, the photoresist layer 54a used as a mask in patterning the field oxidation mask material layer 53 is removed, and the field oxidation is conducted. As shown in FIGS. 5c and 6c, in the field oxidation, it can be known that field oxide films from both sides of the field oxidation mask layer 53a in ‘G’ portion in FIG. 4 encroach into a region under the field oxidation mask layer 53a and merge completely. And, as shown in FIGS. 5d, 6d and 7d, the field oxidation mask layer 53a used as a mask layer in the field oxidation is removed. As shown in FIG. 6d, it can be known that the isolation region which isolates the active region from an adjacent active region along a long axis direction thereof has the field oxidation mask layer 53a together with a device isolation layer under the field oxidation mask layer 53a formed by encroaching of the field oxide films grown from both sides of the isolation region. Thus, the method for fabricating a semiconductor device can secure adequate active region portions at opposite ends of a long axis of the active region at which contact layers of cell storage nodes are formed, by defining the active region larger than actually required active region area and conducting a field oxidation process.

The method for fabricating a semiconductor device has the following advantages.

The adequate area secured in a long axis direction of an active region which is otherwise involved in the greatest reduction allows an adequate process allowance in a cell storage node contact process. And, the reduction of a width of the isolation region between active regions is favorable for high density device packing. As the excessive pre-cleaning process can be avoided, which is done for preventing a reduction of the active region area following excessive growth of the field oxide film, deterioration of the transistor can be prevented.

It will be apparent to those skilled in the art that various modifications and variations can be made in the method for fabricating a semiconductor device of the present invention without departing from the spirit or scope of the invention. Thus, it is intended that the present invention cover the modifications and variations of this invention provided they come within the scope of the appended claims and their equivalents.

What is claimed is:

1. A method for fabricating a semiconductor device for forming field oxide films on an isolation region of a plurality of active regions each having a long axis and a short axis, the method comprising the steps of:
forming first field oxidation mask layers on all active regions;
forming a second field oxidation mask layer on an isolation region which isolates one active region and an adjacent active region in a long axis direction thereof, the second field oxidation mask layer connecting the first field oxidation mask layers; and,
conducting a field oxidation such that field oxide films grow at exposed portions and portion in contact with bottom sides of the second field oxidation mask layer to encroach into the bottom sides of the second field oxidation mask layer, to form a field oxide film on the exposed portions and on an entire portion of the bottom side of the second field oxidation mask layer.

2. A method as claimed in claim 1, wherein the field oxidation mask layer formed on the isolation region has a width smaller than the field oxidation mask layer formed on the active region.

3. A method as claimed in claim 1, wherein the first field oxidation mask layer has a width larger than the active region.

4. A method as claimed in claim 1, wherein both the first field oxidation mask layers and the second field oxidation mask layers are formed of the same material by deposition and patterning at a time.

5. A method for fabricating a semiconductor device, the method comprising the steps of:
(1) forming a buffer oxide film and a field oxidation mask material layer in succession on an entire surface of a semiconductor substrate inclusive of a plurality of separated active regions each with a long axis and a short axis;
(2) forming a photoresist layer on an entire surface of the field oxidation mask material layer;
(3) subjecting the photoresist layer to patterning to leave the photoresist layer only on an isolation region which isolates an active region and an adjacent active region in a long axis direction thereof;
(4) using the patterned photoresist layer as a mask in removing the exposed field oxidation material layer and the buffer oxide film selectively, for exposing a surface of the semiconductor substrate; and,
(5) removing the photoresist layer used as a mask in patterning the field oxidation mask material layer, and conducting field oxidation such that a field oxide film is formed in exposed surfaces of the semiconductor substrate and bottom of the field oxidation mask layer formed on the isolation region which isolates an active region from an adjacent active region in a long axis direction thereof.

6. A method as claimed in claim 5, wherein the field oxidation mask material layer is formed of an anti-oxidation material.

7. A method as claimed in claim 6, wherein the anti-oxidation material is a nitride.

8. A method as claimed in claim 5, wherein a surface of the semiconductor substrate in the isolation region which isolates an active region from an adjacent active region in a short axis direction thereof is fully exposed in the patterning of the field oxidation mask material layer.

9. A method as claimed in claim 5, wherein the field oxidation mask layer formed on the isolation region which isolates an active region from an adjacent active region in a long axis direction thereof has a width smaller than the field oxidation mask layer formed on the active region.

10. A method as claimed in claim 5, wherein the field oxidation mask layer formed on the active region has a width larger than the active region.
